(19) United States
(12) Patent Application Publication
(10) Pub. No.: US 2013/0207104 A1
(43) Pub. Date: Aug. 15, 2013

(54) MANUFACTURING METHOD OF THIN FILM TRANSISTOR AND DISPLAY DEVICE

(71) Applicant: INNOLUX CORPORATION, (US)

(72) Inventor: Kuan-Feng LEE, Miao-Li County (TW)

(73) Assignee: INNOLUX CORPORATION, Miao-Li County (TW)

(21) Appl. No.: 13/764,419

(22) Filed: Feb. 11, 2013

(30) Foreign Application Priority Data
Feb. 14, 2012 (TW) 101104633

(51) Int. Cl. H01L 29/786; H01L 29/66

(52) U.S. Cl. CPC H01L 29/7869; H01L 29/66742
USPC 257/43; 438/158

(57) ABSTRACT

An embodiment of the invention provides a manufacturing method of a thin film transistor including: providing a substrate; sequentially forming a gate electrode, a gate insulating layer covering the gate electrode, and an active layer on the substrate; forming a conductive layer on the active layer and including a source electrode, a drain electrode, and a separating portion connecting therebetween; forming a first photoresist layer on the conductive layer and covering the source electrode and the drain electrode and exposing the separating portion; oxidizing the separating portion into an insulating metal oxide layer so as to electrically insulate the source electrode from the drain electrode; and removing the first photoresist layer.

### CROSS REFERENCE TO RELATED APPLICATIONS

This Application claims priority of Taiwan Patent Application No. 101104633, filed on Feb. 14, 2012, the entirety of which is incorporated by reference herein.

### BACKGROUND OF THE INVENTION

1. Field of the Invention

The present invention relates to a thin film transistor, and in particular relates to a bottom gate thin film transistor.

2. Description of the Related Art

With the progress of display technology, human life is getting more convenient with the assistance of display devices. With demands of being light and thin, the flat panel displays (FPD) have now become the most popular type of displays. Among the variety of FPDs, liquid crystal displays (LCDs) are highly praised by consumers because of advantages such as efficient space utilization, low power consumption, no radiation, and low electromagnetic interference (EMI).

Liquid crystal displays are mainly composed of an active array substrate, a color filter substrate, and a liquid crystal layer located therebetween. The active array substrate has an active region and a periphery circuit region. The active arrays are located in the active region, and the driving circuits having a plurality of bottom gate thin film transistors are located in the periphery circuit region.

In the related art, the manufacturing process of the bottom gate thin film transistor easily suffers from some problems. For example, the forming of a source electrode and a drain electrode may easily damage an active layer therebelow, which results in back channel damage.

### BRIEF SUMMARY OF THE INVENTION

An embodiment of the invention provides a manufacturing method of a thin film transistor including: providing a substrate; sequentially forming a gate electrode, a gate insulating layer covering the gate electrode, and an active layer on the substrate; forming a conductive layer on the active layer and including a source electrode, a drain electrode, and a separating portion connecting therebetween; forming a first photoresist layer on the conductive layer and covering the source electrode and the drain electrode and exposing the separating portion; oxidizing the separating portion into an insulating metal oxide layer so as to electrically insulate the source electrode from the drain electrode; and removing the first photoresist layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1H are cross-sectional views of a manufacturing process of a thin film transistor according to an embodiment of the present invention;

FIG. 2 is a cross-sectional view of a manufacturing process of a thin film transistor according to another embodiment of the present invention;

FIGS. 3A-3F are cross-sectional views of a manufacturing process of a thin film transistor according to an embodiment of the present invention;

FIG. 4 is a cross-sectional view of a manufacturing process of a thin film transistor according to another embodiment of the present invention; and

FIG. 5 is a cross-sectional view of a display according to an embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

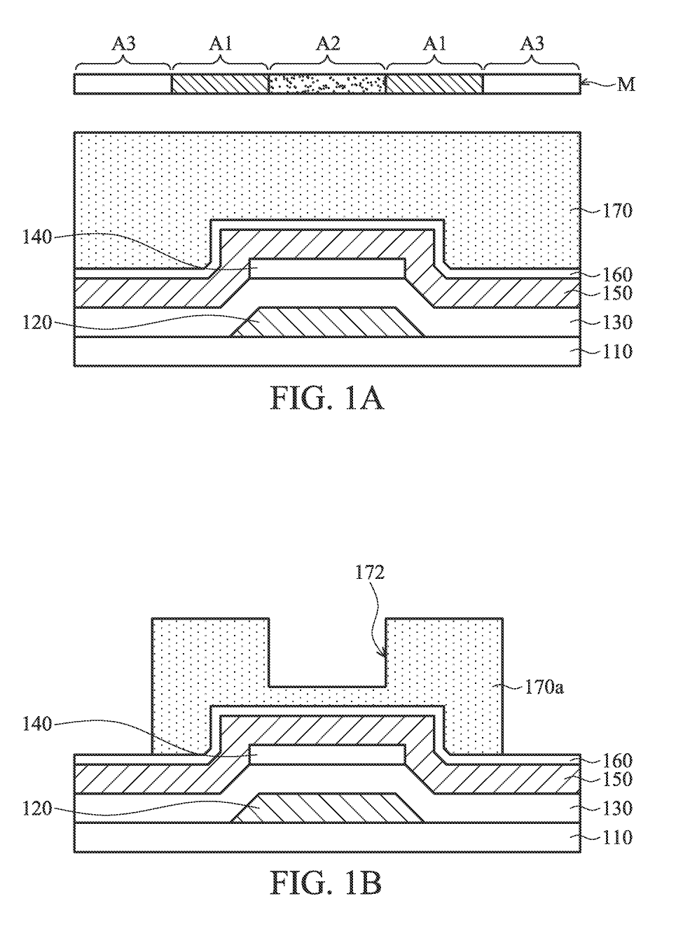

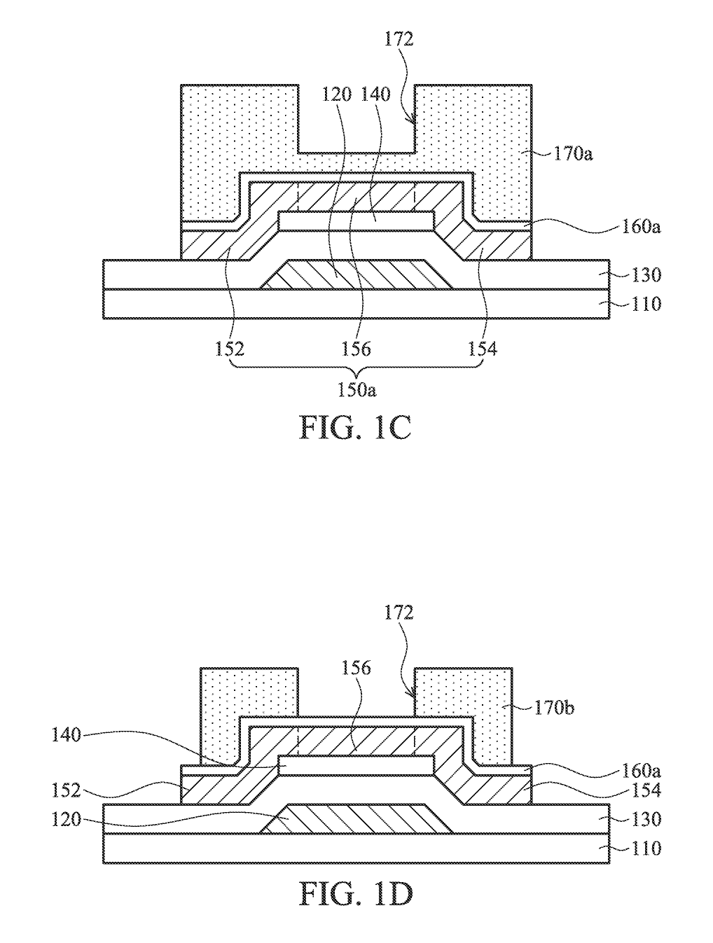

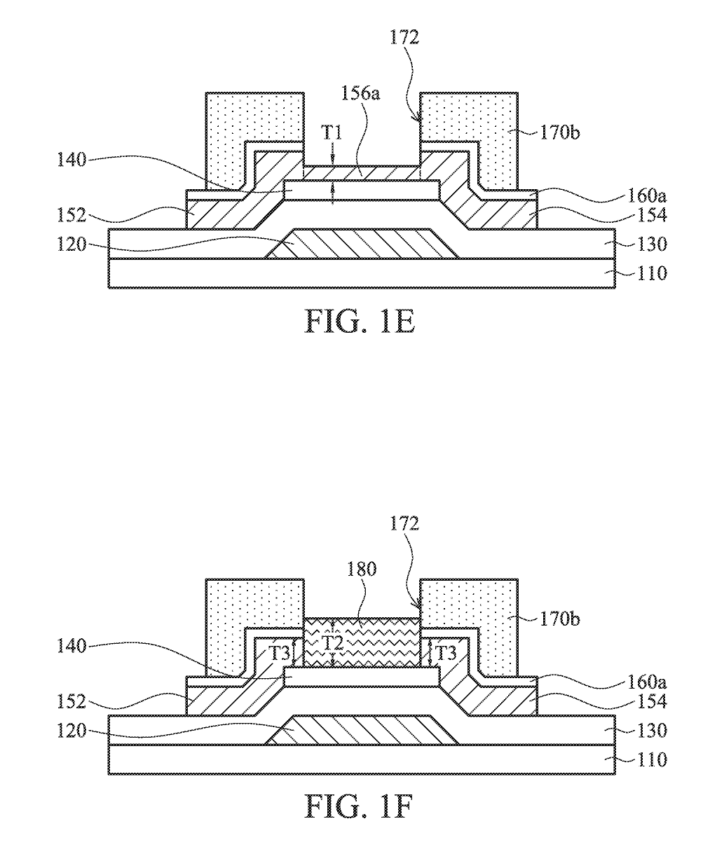

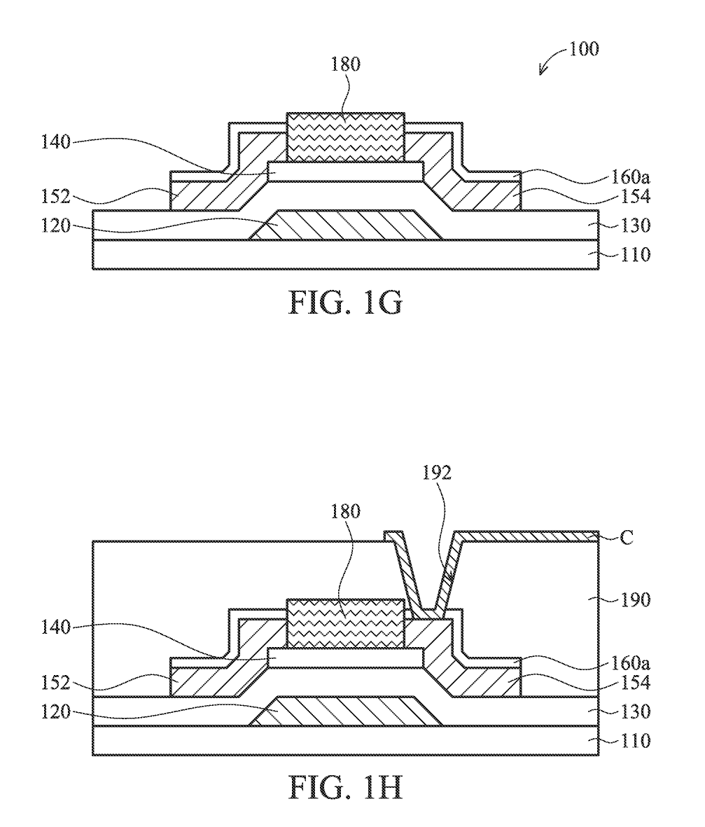

FIGS. 1A-1H are cross-sectional views of a manufacturing process of a thin film transistor according to an embodiment of the present invention. Referring to FIG. 1A, a substrate 110 is provided, for example, a glass substrate. Then, a gate electrode 120 and a gate insulating layer 130 covering the gate electrode 120 are formed on the substrate 110. In one embodiment, the gate electrode 120 may include aluminum and molybdenum, or other suitable conductive materials. The gate insulating layer 130 includes, for example, silicon dioxide or other dielectric materials with high dielectric constants.

Then, an active layer 140 is formed on the gate insulating layer 130, wherein the active layer 140 is above the gate electrode 120. The active layer 140 includes, for example, indium gallium zinc oxide (IGZO), or other semiconductor materials suitable for the active layer.

Then, a conductive material layer 150 covering the active layer 140 is formed on the gate insulating layer 130. The conductive material layer 150 may include aluminum, molybdenum, titanium, copper, or other suitable conductive materials. In the present embodiment, the conductive material layer 150 may include aluminum. In one embodiment, a silicon oxide layer 160 may be optionally formed on the conductive material layer 150 by, for example, physical vapor deposition or chemical vapor deposition.

Then, an oxygen-containing photoresist material layer 170 is formed on the silicon oxide layer 160. The oxygen-containing photoresist material layer 170 includes, for example, a photosensitive organic-inorganic hybrid material, wherein the inorganic material includes siloxane, and the organic material includes an acrylic resin.

Then, referring to FIGS. 1A and 1B, a photolithography process is performed on the oxygen-containing photoresist material layer 170 by using a half-tone photomask M to pattern the oxygen-containing photoresist material layer 170 so as to form an oxygen-containing photoresist capping layer 170a. The half-tone photomask M has an opaque region A1, a transopaque region A2 (with a transmittance ranging from 1% to 99%), and a transparent region A3. The oxygen-containing photoresist capping layer 170a that has been processed by the photolithography process is above the gate electrode 120 and has a recess 172 not penetrating through the oxygen-containing photoresist capping layer 170a, and the oxygen-containing photoresist capping layer 170a expose portions of the silicon oxide layer 160 and the conductive material layer 150 on the periphery of the active layer 140.

Then, referring to FIG. 1C, by using the oxygen-containing photoresist capping layer 170a as an etching mask, the conductive material layer 150 and the silicon oxide layer 160 are patterned to form a conductive layer 150a and a silicon oxide layer 160a. The conductive layer 150a includes a source electrode 152, a drain electrode 154, and a separating portion 156 between the source electrode 152 and the drain electrode 154, wherein the recess 172 is right above the separating portion 156.

Then, referring to FIG. 1D, an plasma ashing process is optionally performed on the oxygen-containing photoresist capping layer 170a to remove the oxygen-containing photoresist capping layer 170a under the bottom of the recess 172 to form an oxygen-containing photoresist layer 170b to expose a portion of the silicon oxide layer 160a and the separating portion 156. In this case, the silicon oxide layer 160a may serve as an etching stop layer in the plasma ashing process.

Then, referring to FIG. 1E, an oxygen plasma etching process is performed to the separating portion 156 by using the oxygen-containing photoresist layer 170b as a mask to thin the separating portion 156 into a thinned separating portion 156a. In one embodiment, the thinned separating portion 156a has a thickness ranging from about 100 Å to about 500 Å.

Then, referring to FIG. 1F, the thinned separating portion 156a is oxidized to form an insulating metal oxide layer 180 to electrically insulate the source electrode 152 and the drain electrode 154. In one embodiment, the oxidizing of the thinned separating portion 156a includes, for example, disposing the thinned separating portion 156a in an atmospheric environment (for about one day), disposing the thinned separating portion 156a in an oxygen-containing environment and heating the thinned separating portion 156a (at a temperature ranging about 200° C. to 500° C. for less than one day), disposing the thinned separating portion 156a in a moisture-containing environment, or other methods suitable to fully oxidize the thinned separating portion 156a.

It should be noted that, in the present embodiment, the separating portion 156 is thinned into the thinned separating portion 156a by the oxygen plasma etching process, and then the thinned separating portion 156a is oxidized into the insulating metal oxide layer 180, such that the source electrode 152 and the drain electrode 154 are electrically insulated from each other. That is to say, in the present embodiment, the thinned separating portion 156a is left after the etching of the separating portion 156 to prevent the etching process from damaging the active layer 140 under the separating portion 156, and then the thinned separating portion 156a is oxidized to electrically insulate the source electrode 152 from the drain electrode 154. Thus, the present embodiment can effectively prevent the conventional problem where the active layer under the separating portion is damaged when the separating portion is fully etched away.

In the present embodiment, the thinned separating portion 156a is located in a high oxygen-containing environment constructed by the high oxygen-containing photoresist layer 170b, the silicon oxide layer 160a, and the oxygen plasma etching process, which helps the thinned separating portion 156a to be fully oxidized into a stable insulating metal oxide layer 180. Furthermore, the insulating metal oxide layer 180 can protect the active layer 140 therebelow from environmental moisture and pollution.

In the present embodiment, the conductive layer 150a (including the source electrode 152, the drain electrode 154, and the separating portion 156) includes aluminum, and therefore the insulating metal oxide layer 180 may include aluminum oxide. In other embodiments, the conductive layer 150a includes titanium or copper, and therefore the insulating metal oxide layer 180 may include titanium oxide or copper oxide.

A thickness T2 of the insulating metal oxide layer 180 may larger than one-third of a thickness T3 of the source electrode 152 or the drain electrode 154. In one embodiment, the thickness T2 of the insulating metal oxide layer 180 may be larger than the thickness T3 of the source electrode 152 or the drain electrode 154. The thickness T2 of the insulating metal oxide layer 180 may be, for example, about 0.1 μm-1 μm.

Then, referring to FIG. 1G, the oxygen-containing photoresist layer 170b is removed. Up to this point, the thin film transistor 100 of the present embodiment is completed substantially. Then, referring to FIG. 1H, an insulating protective layer 190 may be blanketly formed on the gate insulating layer 130, and an opening 192 penetrates through the insulating protective layer 190 and the silicon oxide layer 160a to expose the drain electrode 154. Then, a conductive layer C may be formed on the insulating protective layer 190 and extends into the opening 192 to connect to the drain electrode 154. In another embodiment (not shown), the opening 192 may expose the source electrode 152, and the conductive layer C may extend into the opening 192 to connect to the source electrode 152.

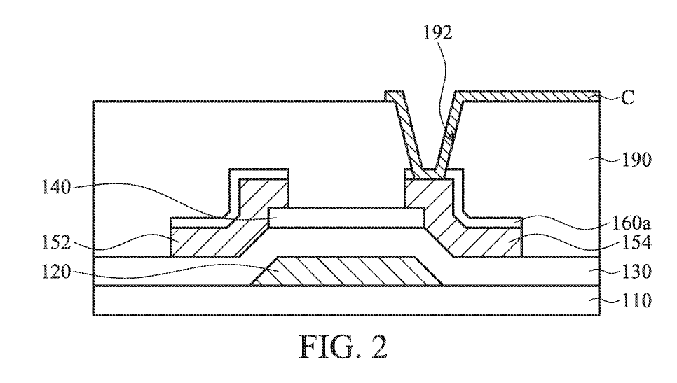

FIG. 2 is a cross-sectional view of a manufacturing process of a thin film transistor according to another embodiment of the present invention. As shown in FIG. 2, in another embodiment, the insulating metal oxide layer 180 may be removed before the forming of the insulating protective layer 190.

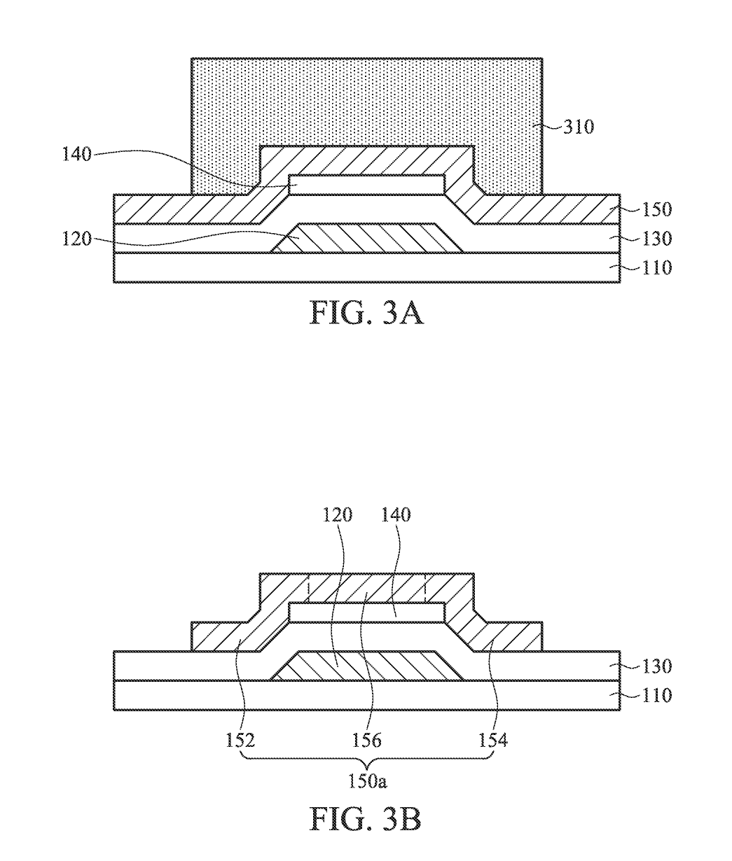

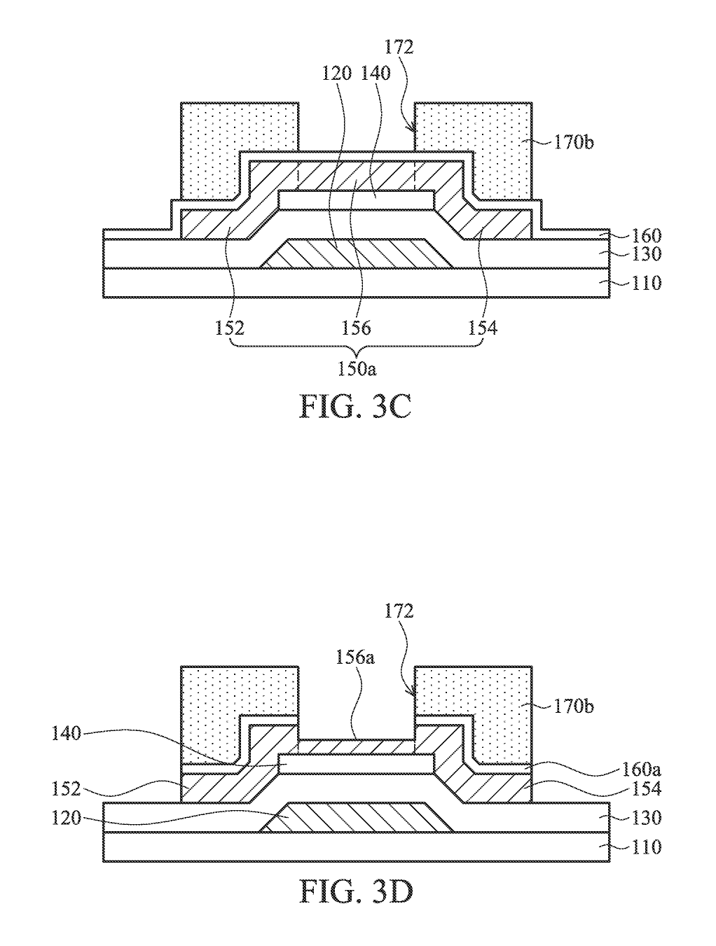

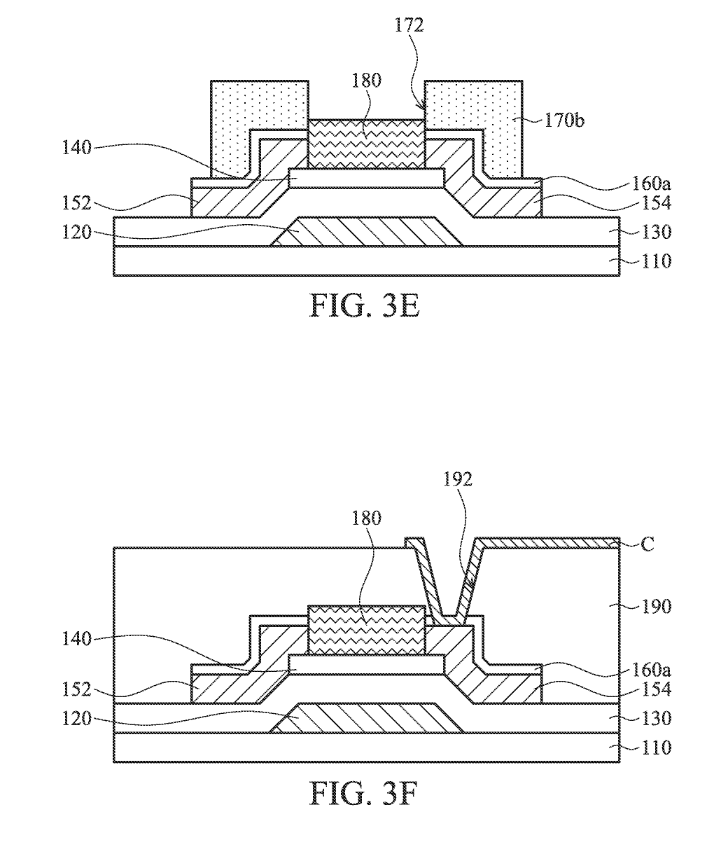

FIGS. 3A-3F are cross-sectional views of a manufacturing process of a thin film transistor according to an embodiment of the present invention. It should be noted that the device materials of the present embodiment are similar to that of the embodiment in FIGS. 1A-1G, and thus not repeated herein.

Referring to FIG. 3A, a substrate 110 is provided. Then, a gate electrode 120 and a gate insulating layer 130 covering the gate electrode 120 are formed on the substrate 110. Then, an active layer 140 is formed on the gate insulating layer 130, wherein the active layer 140 is above the gate electrode 120. Then, a conductive material layer 150 covering the active layer 140 is formed on the gate insulating layer 130. In the present embodiment, the conductive material layer 150 may include aluminum. Then, a photoresist layer 310 is formed on the conductive material layer 150, and the photoresist layer 310 is above the active layer 140 and exposes a portion of the conductive material layer 150 on the periphery of the active layer 140.

Then, referring to FIG. 3B, the conductive material layer 150 exposed by the photoresist layer 310 is etched away by using the photoresist layer 310 as an etching mask to form a conductive layer 150a. The conductive layer 150a includes a source electrode 152, a drain electrode 154, and a separating portion 156 between the source electrode 152 and the drain electrode 154. Then, the photoresist layer 310 is removed.

Then, referring to FIG. 3C, a silicon oxide layer 160 may be optionally blanketly formed on the conductive layer 150a. Then, an oxygen-containing photoresist layer 170b is formed on the silicon oxide layer 160, and the oxygen-containing photoresist layer 170b covers the source electrode 152 and the drain electrode 154 and exposes the separating portion 156. Then, referring to FIG. 3D, an oxygen plasma etching process is performed on the separating portion 156 by using the oxygen-containing photoresist layer 170b as an etching mask to thin the separating portion 156 into a thinned separating portion 156a. In one embodiment, the oxygen plasma etching process also removes the silicon oxide layer 160 exposed by the oxygen-containing photoresist layer 170b to form a silicon oxide layer 160a.

Then, referring to FIG. 3E, the thinned separating portion 156a is oxidized to form an insulating metal oxide layer 180 to electrically insulate the source electrode 152 from the drain electrode 154. In one embodiment, the oxidizing of the thinned separating portion 156a includes, for example, disposing the thinned separating portion 156a in an atmospheric environment (for about one day), disposing the thinned separating portion 156a in an oxygen-containing environment and heating the thinned separating portion 156a, disposing the thinned separating portion 156a in a moisture-containing environment, or other methods suitable to fully oxidize the thinned separating portion 156a.

In the present embodiment, the conductive layer 150a (including the source electrode 152, the drain electrode 154, and the separating portion 156) includes aluminum, and therefore the insulating metal oxide layer 180 may include aluminum oxide. In other embodiments, the conductive layer 150a includes titanium or copper, and therefore the insulating metal oxide layer 180 may include titanium oxide or copper oxide.

Then, referring to FIG. 3F, the oxygen-containing photoresist layer 170b is removed. Then, an insulating protective layer 190 may be blanketly formed on the gate insulating layer 130, and the insulating protective layer 190 has an opening 192 exposing the drain electrode 154. Then, a conductive layer C may be formed on the insulating protective layer 190 and extends into the opening 192 to connect to the drain electrode 154. In another embodiment (not shown), the opening 192 may expose the source electrode 152, and the conductive layer C may extend into the opening 192 to connect to the source electrode 152.

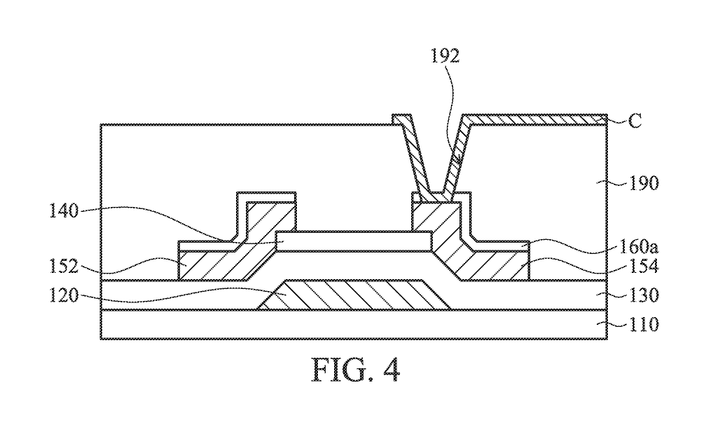

FIG. 4 is a cross-sectional view of a manufacturing process of a thin film transistor according to another embodiment of the present invention. As shown in FIG. 4, in another embodiment, the insulating metal oxide layer 180 may be removed before the forming of the insulating protective layer 190.

It should be noted that the embodiments described above take the bottom gate thin film transistors as examples, but the invention is not limited thereto. For example, the thin film transistor of the invention and the manufacturing methods thereof may also be applied to top gate thin film transistors.

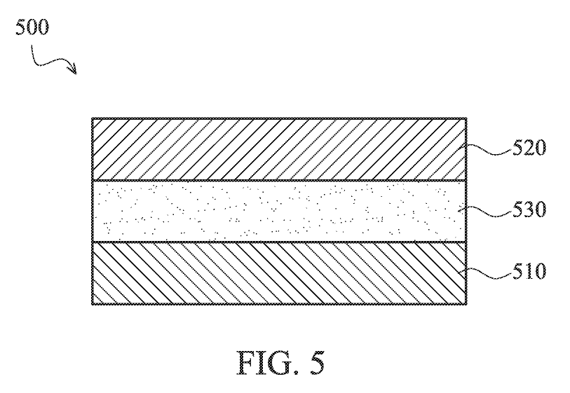

FIG. 5 is a cross-sectional view of a display according to an embodiment of the present invention. Referring to FIG. 5, a display 500 of the present embodiment includes a thin film transistor substrate 510, a substrate 520, and a display medium 530 sandwiched therebetween. The thin film transistor substrate 510 may be the thin film transistor substrate shown in FIGS. 1H, 2, 3F, or 4, and the display medium 530 may be a liquid crystal layer or an organic light emitting layer. The substrate 520 is, for example, a color filter substrate or a transparent substrate.

In view of the foregoing, in the present invention, the thinned separating portion is left after the etching of the separating portion (connecting the source electrode and the drain electrode) to prevent the etching process from damaging the active layer under the separating portion, and then the thinned separating portion is oxidized to electrically insulate the source electrode from the drain electrode.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A manufacturing method of a thin film transistor, comprising:
providing a substrate;
forming a gate electrode disposed on the substrate;
forming a gate insulating layer disposed on the substrate and covering the gate electrode;
forming an active layer disposed on the gate insulating layer, wherein the active layer is disposed on a portion of the gate electrode;
forming a conductive layer disposed on the active layer, wherein the conductive layer includes a source electrode, a drain electrode, and a separating portion between the source electrode and the drain electrode;
forming a first photoresist layer disposed on the conductive layer, wherein the first photoresist layer covers the source electrode and the drain electrode and exposes the separating portion;
oxidizing the separating portion into an insulating metal oxide layer so as to electrically insulate the source electrode from the drain electrode; and
removing the first photoresist layer.

2. The manufacturing method of the thin film transistor as claimed in claim 1, wherein the oxidizing of the separating portion comprises:
performing an oxygen plasma etching process to the separating portion by using the first photoresist layer as a mask to thin the separating portion into a thinned separating portion; and
oxidizing the thinned separating portion.

3. The manufacturing method of the thin film transistor as claimed in claim 2, wherein the oxidizing of the thinned separating portion comprises:
disposing the thinned separating portion in an oxygen-containing environment and heating the thinned separating portion; or
disposing the thinned separating portion in a moisture-containing environment.

4. The manufacturing method of the thin film transistor as claimed in claim 2, wherein a thickness of the thinned separating portion substantially ranges from 200 Å to 500 Å.

5. The manufacturing method of the thin film transistor as claimed in claim 1, further comprising:
removing the insulating metal oxide layer.

6. The manufacturing method of the thin film transistor as claimed in claim 1, wherein the first photoresist layer includes a photosensitive organic-inorganic hybrid material.

7. The manufacturing method of the thin film transistor as claimed in claim 6, wherein an inorganic material of the photosensitive organic-inorganic hybrid material includes siloxane.

8. The manufacturing method of the thin film transistor as claimed in claim 1, wherein the forming of the conductive layer and the first photoresist layer comprises:
forming a conductive material layer on the gate insulating layer, wherein the conductive material layer covers the active layer;
forming an oxygen-containing photoresist material layer on the conductive material layer;
performing a photolithography process on the oxygen-containing photoresist material layer by using a half-tone photomask to pattern the oxygen-containing photoresist material layer so as to form an oxygen-containing photoresist capping layer, wherein the oxygen-containing photoresist capping layer is above the gate electrode and has a recess not passing through the oxygen-containing photoresist capping layer;
patterning the conductive material layer by using the oxygen-containing photoresist capping layer as an etching mask to form the conductive layer; and
removing the oxygen-containing photoresist capping layer constructing a bottom of the recess to form the first photoresist layer, wherein the recess exposes the separating portion.

9. The manufacturing method of the thin film transistor as claimed in claim 8, wherein the removing of the oxygen-containing photoresist capping layer constructing the bottom of the recess comprises:
performing a plasma ashing process to the oxygen-containing photoresist capping layer.

10. The manufacturing method of the thin film transistor as claimed in claim 1, further comprising:
forming a silicon oxide layer on the conductive layer before the forming of the first photoresist layer, wherein the first photoresist layer exposes a portion of the silicon oxide layer after the forming of the first photoresist layer.

11. The manufacturing method of the thin film transistor as claimed in claim 1, wherein the forming of the conductive layer comprises:
forming a conductive material layer covering the active layer on the gate insulating layer;
forming a second photoresist layer on the conductive material layer, wherein the second photoresist layer is above the active layer and exposes the conductive material layer on a periphery of the active layer;
removing the conductive material layer exposed by the second photoresist layer by using the second photoresist layer as an etching mask to form the conductive layer; and
removing the second photoresist layer.

12. The manufacturing method of the thin film transistor as claimed in claim 1, wherein the first photoresist layer is an oxygen-containing photoresist layer.

13. A display device, comprising:
a substrate;
a gate electrode on the substrate;
a gate insulating layer disposed on the substrate and covering the gate electrode;
an active layer disposed on the gate insulating layer and disposed on a portion of the gate electrode;
a source electrode and a drain electrode disposed on the active layer and at two opposite sides of the gate electrode, wherein the source electrode and the drain electrode are separated by a recess; and
an insulating metal oxide layer disposed on the active layer and filling into the recess, wherein the source electrode and the drain electrode include a metal material corresponding to the insulating metal oxide layer.

14. The display device as claimed in claim 13, wherein the active layer includes indium gallium zinc oxide.

15. The display device as claimed in claim 13, wherein a thickness of the insulating metal oxide layer substantially ranges from 0.1 μm to 1 μm.

16. The display device as claimed in claim 13, wherein the metal material is aluminum, and the insulating metal oxide layer is an aluminum oxide layer.

17. The display device as claimed in claim 13, wherein a thickness of the insulating metal oxide layer is larger than one-third of a thickness of the source electrode or the drain electrode.

18. The display device as claimed in claim 13, further comprising:
a silicon oxide layer covering the source electrode and the drain electrode.
